(19) United States
(12) Patent Application Publication
(10) Pub. No.: US 2025/0275244 A1
(43) Pub. Date: Aug. 28, 2025

(54) ARRAY SUBSTRATE

(71) Applicant: HannsTouch Holdings Company, Tainan City (TW)

(72) Inventor: Sheng-Chia Lin, Tainan City (TW)

(73) Assignee: HannsTouch Holdings Company, Tainan City (TW)

(21) Appl. No.: 18/585,016

(22) Filed: Feb. 22, 2024

(51) Int. Cl. H01L 27/12

(52) U.S. Cl. CPC H10D 86/60; H10D 86/441

(57) ABSTRACT

An array substrate includes a substrate, a first pixel electrode, a second pixel electrode, a first scan line, a second scan line and a data line. The first and second pixel electrodes are disposed on the substrate and arranged along a first direction. The first and second scan lines are disposed on the substrate and extend along the first direction, wherein the first and second pixel electrodes are disposed between the first and second scan lines. The first and second traces are disposed on the substrate and extend along a second direction different from the first direction, wherein the first and second traces are electrically connected to the first and second scan lines, respectively, the first trace crosses and is electrically insulated from the second scan line, and the data line is disposed between the first trace and the second trace.

### BACKGROUND OF THE INVENTION

### 1. Field of the Invention

The present invention relates to an array substrate, and more particularly to an array substrate applied to an electronic device with narrow border.

### 2. Description of the Prior Art

In order to meet requirements on appearance designs and space utilization, display devices have been developed to have reduced border width. At present, it has been developed to use traces formed of the same conductive layer with the data lines to bridging scan lines, and the traces are disposed in the display region. However, this approach will increase the number of signal lines in the display region, thus increasing the coupling capacitance between adjacent signal lines and further adversely affecting the display quality. Therefore, how to meet the requirement on reduction of border width while maintaining the display quality is one of the development objectives for those skilled in the art.

### SUMMARY OF THE INVENTION

An embodiment of the present invention provides an array substrate, which includes a substrate, a first pixel electrode, a second pixel electrode, a first scan line, a second scan line and a data line. The first pixel electrode and the second pixel electrode are disposed on the substrate and arranged along a first direction. The first scan line and the second scan line are disposed on the substrate and extend along the first direction, wherein the first pixel electrode and the second pixel electrode are disposed between the first scan line and the second scan line. The first trace and the second trace are disposed on the substrate and extend along a second direction different from the first direction, wherein the first trace is electrically connected to the first scan line, the second trace is electrically connected to the second scan line, the first trace crosses and is electrically insulated from the second scan line, and the first trace and the second trace are formed of a first conductive layer. The data line is disposed on the substrate and extends along the second direction, wherein in the top view of the array substrate the data line is disposed between the first pixel electrode and the second pixel electrode, the data line crosses the second scan line, the data line is formed of a second conductive layer different from the first conductive layer, and the data line is disposed between the first trace and the second trace.

Another embodiment of the present invention provides an array substrate, which includes a substrate, a first scan line, a second scan line, a first trace, a second trace and a data line. The first scan line and the second scan line are disposed on the substrate and extend along the first direction, wherein each of the first scan line and the second scan line comprises a plurality of line sections and a plurality of first bridging sections. The first trace and the second trace are disposed on the substrate and extend along a second direction different from the first direction, wherein the first trace is electrically connected to the first scan line, and the second trace is electrically connected to the second scan line. The data line is disposed on the substrate and extends along the second direction, wherein the data line crosses one of the plurality of first bridging sections of the first scan line and one of the plurality of first bridging sections of the second scan line. A number of the plurality of first bridging sections of the first scan line is the same as a number of the plurality of first bridging sections of the second scan line. The one of the first bridging sections of the second scan line in the data line in the top view of the array substrate overlaps the data line and the first trace.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates a top view of an array substrate according to a first embodiment of the present invention.

FIG. 2 schematically illustrates a cross-sectional view of FIG. 1 taken along a line A-A′.

FIG. 3 schematically illustrates a top view of an array substrate according to a second embodiment of the present invention.

FIG. 4 schematically illustrates a cross-sectional view of FIG. 3 taken along a line B-B′.

FIG. 5 schematically illustrates a top view of an array substrate according to a variation of the second embodiment of the present invention.

FIG. 6 schematically illustrates a top view of an array substrate according to another variation of the second embodiment of the present invention.

FIG. 7 schematically illustrates a top view of an array substrate according to a third embodiment of the present invention.

FIG. 8 schematically illustrates a cross-sectional view of FIG. 7 taken along a line C-C′.

FIG. 9 schematically illustrates a top view of an array substrate according to a variation of the third embodiment of the present invention.

FIG. 10 schematically illustrates a top view of an array substrate according to another variation of the third embodiment of the present invention.

### DETAILED DESCRIPTION

The contents of the present invention will be described in detail with reference to specific embodiments and drawings. It is noted that, for purposes of illustrative clarity and being easily understood by the readers, the following drawings may be simplified schematic diagrams, and elements therein may not be drawn to scale. The numbers and dimensions of the elements in the drawings are just illustrative and are not intended to limit the scope of the present invention.

In the present invention, the array substrate may be applied to an electronic device that needs a pixel array. For example, the electronic device may be a display device, an image sensing device, an X-ray sensing device, or any other suitable device. The display device may be, for example, a non-self-luminous display device or a self-luminous display device. The non-self-luminous display device may include, for example, a liquid crystal display device or any other suitable device. The self-luminous display device may include, for example, an organic light-emitting diode display device, an inorganic light-emitting diode display device, or any other suitable device. Depending on the types of display devices, the display device may further include another substrate and/or elements in addition to the array substrate. For example, if the display device is the liquid crystal display device, the display device may include the array substrate, a color filter substrate and a liquid crystal layer, and the liquid crystal layer may be disposed between the color filter substrate and the array substrate, but it is not limited thereto. If the display device is the self-luminous display device, the display device may include the array substrate, light emitting diodes and an encapsulation layer, in which the light emitting diodes and the encapsulation layer are disposed on the array substrate, but it is not limited thereto. The array substrate in the following description is applied to a display device as an example, but it is not limited thereto.

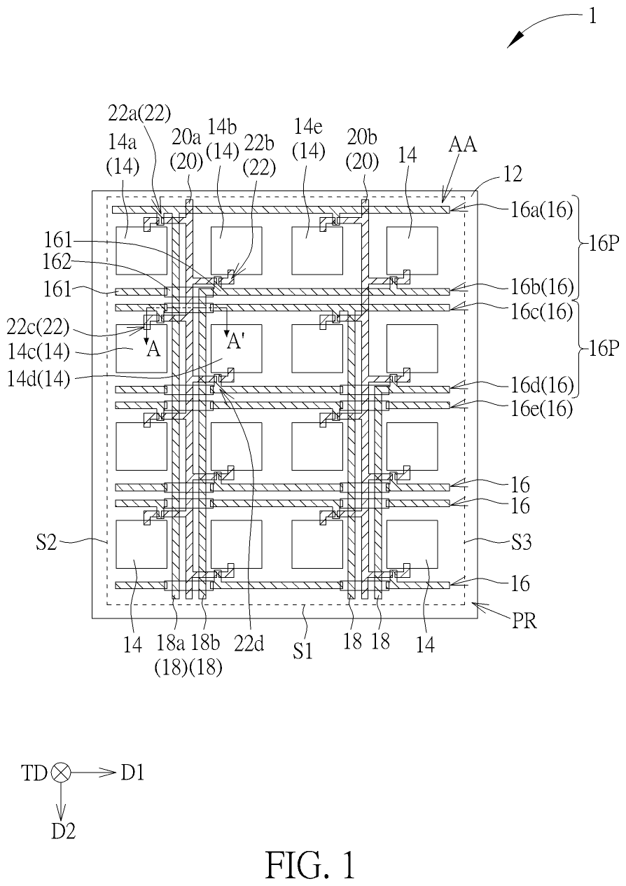

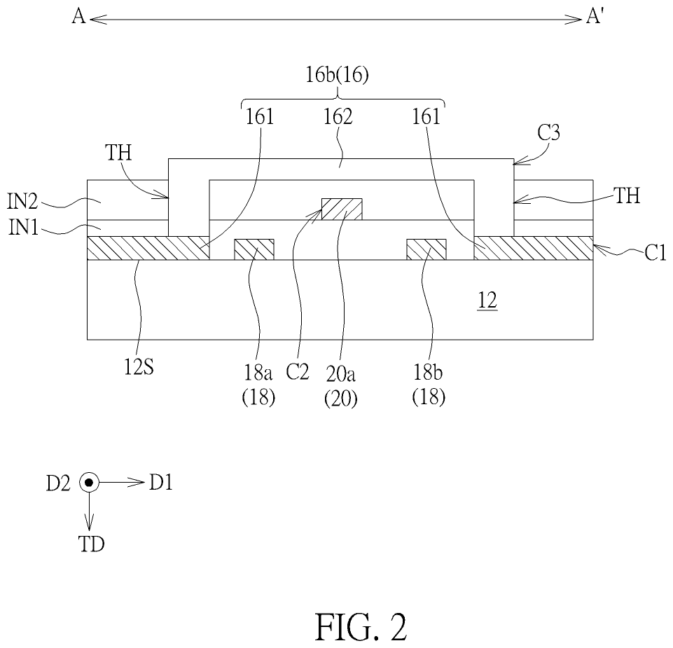

Refer to FIG. 1 and FIG. 2, in which FIG. 1 schematically illustrates a top view of an array substrate according to a first embodiment of the present invention, and FIG. 2 schematically illustrates a cross-sectional view of FIG. 1 taken along a line A-A′. For clarity, FIG. 1 and FIG. 2 only show some of elements included in the array substrate, but the array substrate of the present invention is not limited to the configuration as shown. As shown in FIG. 1, the array substrate 1 is applied to the display device and may include an active region AA and a peripheral region PR, wherein the peripheral region PR is disposed at at least one side of the active region AA. In an embodiment as illustrated in FIG. 1, the peripheral region PR may surround the active region AA, but not limited thereto. The active region AA of the array substrate 1 may, for example, correspond to a display region of the display device, but it is not limited thereto.

In an embodiment as illustrated in FIG. 1, the array substrate 1 may be a dual-gate type of array substrate, but it is not limited thereto. In detail, the array substrate 1 may include a substrate 12, a plurality of pixel electrodes 14, a plurality of scan lines 16, a plurality of traces 18, a plurality of data lines 20 and a plurality of switch elements 22, wherein the pixel electrodes 14, the scan lines 16, the traces 18, the data lines 20 and the switch elements 22 are disposed on the substrate 12 in the active region AA. The substrate 12 may be, for example, a flexible substrate, or a non-flexible substrate. The substrate 12 may include, for example, glass, quartz, sapphire, acrylic, polyimide (PI), any other suitable material, or a combination of the above-mentioned materials, but it is not limited thereto.

As shown in FIG. 1, each of the pixel electrodes 14 may be electrically connected to a corresponding one of the switch elements 22. If the array substrate 1 is applied to a display device, pixel voltages to be applied to the pixel electrodes 14 may be changed through the switch elements 22, thereby adjusting brightness of pixels or sub-pixels of the display device, but it is not limited thereto. In an embodiment as illustrated in FIG. 1, the pixel electrodes 14 may be arranged in the active region AA as an array, wherein each row of the array may extend along a first direction D1, and each column of the array may extend along a second direction D2, which is different from the first direction D1, e.g., perpendicular to the first direction D1. However, it is not limited thereto. For example, the pixel electrodes 14 may include a pixel electrode 14a, a pixel electrode 14b, a pixel electrode 14c and a pixel electrode 14d, wherein the pixel electrode 14a and the pixel electrode 14b are arranged along the first direction D1, and the pixel electrode 14c and the pixel electrode 14d are arranged along the first direction D1, the pixel electrode 14a and pixel electrode 14c are arranged along the second direction D2, and the pixel electrode 14b and pixel electrode 14d are arranged along the second direction D2. The arrangement of the pixel electrodes 14 according to the present invention is not limited to the above-mentioned one.

The scan lines 16 respectively extend along the first direction D1 and are arranged along the second direction D2. In this embodiment, the scan lines 16 are grouped into a plurality of scan line pairs 16P, which are arranged along the second direction D2. Each of the scan line pairs 16P consists of two adjacent scan lines 16. A row of pixel electrodes 14 is disposed between two of the scan lines 16, which belong to the same scan line pair 16P, so that the pixel voltages applied to the pixel electrodes 14 in the same row may be changed through the scan lines 16 of the same scan line pair 16P, but it is not limited thereto. In this embodiment, the pixel voltages applied to the pixel electrodes 14 in the same row and connected to the same data line 20 may be changed sequentially through different scan lines 16 of the same scan line pair 16P. For example, the scan lines 16 may include a scan line 16a, a scan line 16b, a scan line 16c and a scan line 16d, wherein the scan line 16a and the scan line 16b constitute one scan line pair 16P, and the scan line 16c and the scan line 16d constitute another scan line pair 16P. The pixel electrode 14a and the pixel electrode 14b are disposed between the scan line 16a and the scan line 16b, and the pixel voltages of which are changed through the scan line 16a and the scan line 16b, respectively. The pixel electrode 14c and the pixel electrode 14d are disposed between the scan line 16c and the scan line 16d, and the pixel voltages of which are changed through the scan line 16c and the scan line 16d, respectively. In other words, counting the pixel electrodes 14 in the same row from left to right of the active region AA, the odd-numbered pixel electrodes 14 may be controlled through the scan line 16a, and the even-numbered pixel electrodes 14 may be controlled through the scan line 16b, but it is not limited thereto.

The traces 18 are electrically connected to the scan lines 16, respectively and extend from the corresponding scan lines 16 to the peripheral region PR at a side, e.g., a first side S1, of the active region AA along the second direction, thereby electrically connecting the scan lines 16 to an element, e.g., a gate driving circuit, in the peripheral region PR. In this case, the traces 18 may cross and be electrically insulated from the scan lines 16 disposed between the corresponding scan lines 16 and the first side S1 of the active region AA. For example, the traces 18 may include a trace 18a and a trace 18b, which are electrically connected to the scan line 16a and the scan line 16b, respectively, and the trace 18a crosses and is electrically insulated from the scan line 16b. It is to be noted that since the traces 18 electrically connected to the corresponding scan lines 16 may extend to the peripheral region PR along the second direction D2, it is not necessary to form traces at two ends of one of the scan lines 16. Accordingly, the number of the traces at left side and right side of the scan lines 16 may be reduced, so that the width of the peripheral region PR at a second side S2 of the active region AA and the width of the peripheral region PR at a third side S3 of the active region AA may be reduced. Therefore, the display device may have a narrow border. In some embodiments, one of the traces 18 may cross the pixel electrodes 14 in the same column and disposed between the corresponding scan line 16 and the first side S1 of the active region AA.

In the embodiment as illustrated in FIG. 1, the lengths of the traces 18 in the second direction D2 may differ from each other as distances from the scan lines 16 to the first side S1 of the active region AA. In an embodiment, the traces 18 are gradually shorter along a specified direction, e.g., the first direction D1. For example, longer traces 18 are closer to the second side S2 or the third side S3 of the active region AA, but it is not limited thereto. In some embodiments, the sequence of arranging the traces 18 in the first direction D1 may not depend on the sequence of the sizes in length of the traces.

In the embodiment as illustrated in FIG. 1, at least one of the scan lines 16 may include at least two line sections 161 and at least one bridging section 162 electrically connected between the line sections 161. In other words, the line sections 161 and the bridging section(s) 162 are interconnected to form the scan line 16. For example, each of the scan lines 16 disposed between the first side S1 of the active region AA and the scan line 16 (e.g., the scan line 16a shown in FIG. 1) farthest from the first side S1 may include at least one bridging section 162. In an embodiment, the scan lines 16 disposed between two adjacent rows of pixel electrodes 14 may include the same number of line sections 161 and the same number of bridging section 162, but it is not limited thereto. For example, each of the scan line 16b and the scan line 16c may include two line sections 161 and one bridging section 162, each of the scan line 16d and the scan line 16e may include three line sections 161 and two bridging sections 162, and so on.

As shown in FIG. 2, the traces 18 and the bridging sections 162 may be formed of different conductive layers. Therefore, the traces 18 may overlap the bridging sections 162 in the top view of the array substrate 1, such that the traces 18 can cross the scan lines 16 while being electrically insulated from the scan lines 16. For example, the line sections 161 and the traces 18 are formed of a conductive layer C1, and the bridging sections 162 are formed of a conductive layer C3 different from the conductive layer C1, so that the bridging section 162 of the scan line 16b may cross and overlap the trace 18a. Under this circumstance, the bridging section 162 of the scan line 16c as shown in FIG. 1 may cross the trace 18a and the trace 18b, and so on. In an embodiment, each of the line sections 161 and the bridging section(s) 162 may be of a strip shape, but it is not limited thereto. In this disclosure, the top view of the array substrate may, for example, be viewed along a top view direction TD perpendicular to a top surface 12S of the substrate 12, as shown in FIG. 2.

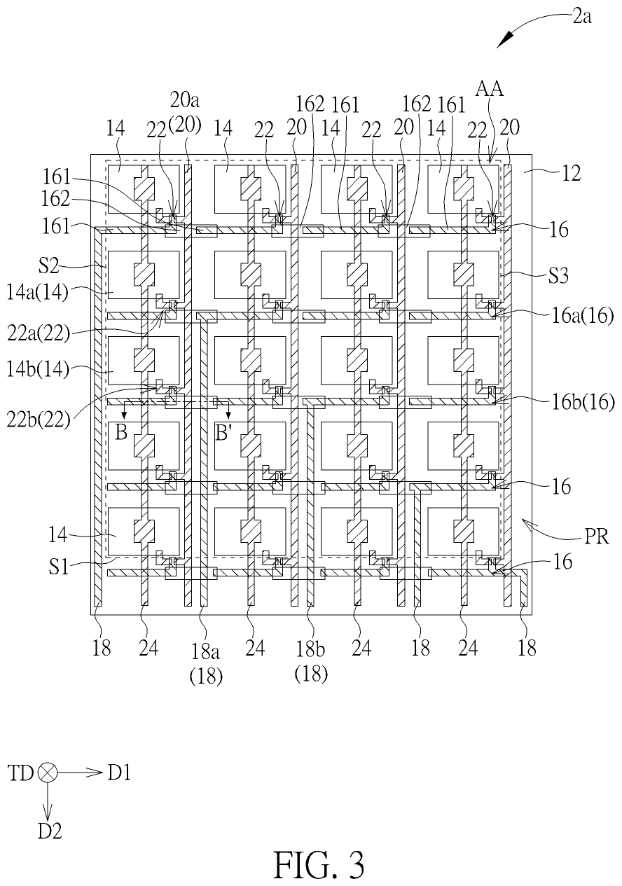

In some embodiments, the scan lines 16 may respectively include the same number of line sections 161 and the same number of bridging sections 162. In an example, the number of bridging sections 162 included in each scan line 16, as shown in FIG. 3, may be the same as a number of the data lines 20. By designing the scan lines 16 with the same number of bridging sections 162, the resistances of the scan lines 16 may be close to each other, so as to avoid abnormality of the display device and improve displaying quality. Under this circumstance, in some embodiments, the traces 18 in the active region AA may have the same length, and each trace 18 may cross the scan lines 16, which are not electrically connected thereto, thereby unifying the coupling capacitances of the scan lines 16. However, it is not limited thereto.

As shown in FIG. 1, the data lines 20 extend along the second direction D2 and cross the scan lines 16, and the data lines 20 are electrically insulated from the scan lines 16. In the embodiments as illustrated in FIG. 1 and FIG. 2, the data lines 20 may be formed of a conductive layer C2 different from the conductive layer C1 and the conductive layer C3, but it is not limited thereto. The bridging section 162 or the line sections 161 of one of the scan lines 16 may cross one of the data lines 20 while being electrically insulated from the data line 20. For example, the data lines 20 may include a data line 20a and a data line 20b, which are arranged along the first direction D1, and the bridging section 162 of the scan line 16b or 16c may cross the data line 20a. Furthermore, one of the bridging sections 162 of the scan line 16d or 16e may cross the data line 20a, and the other of the bridging sections 162 of the scan line 16d or 16e may cross the data line 20b. In some embodiments, the scan lines 16 respectively include the same number of line sections 161 and the same number of bridging sections 162. Meanwhile, each of the data lines 20 may cross one of the bridging sections 162 of each scan line 16, but it is not limited thereto.

In an embodiment, one of the data lines 20 may be disposed between two adjacent columns of the pixel electrodes 14 in the top view of the array substrate 1 and electrically connected to the pixel electrodes 14 in the two adjacent columns of the pixel electrodes 14. Therefore, each data line 20 may be used for providing the pixel voltage of two adjacent columns of the pixel electrodes 14, thereby reducing the number of data lines 20. On the other hand, two columns of pixel electrodes 14 may be disposed between two adjacent data lines 20. For example, the data line 20a may be disposed between the pixel electrode 14a and the pixel electrode 14b and between the pixel electrode 14c and the pixel electrode 14d and be electrically connected to the pixel electrodes 14a-14d. In addition, the pixel electrode 14b and the pixel electrode 14e arranged along the first direction D1 are disposed between two adjacent data lines 20a and 20b. Furthermore, in the top view of the array substrate 1, one of the data lines 20 may be disposed between two of the traces 18 electrically connected to the scan lines 16 belonging to the same scan line pair 16P. For example, the data line 20a may be disposed between the trace 18a and the trace 18b, but it is not limited thereto.

As shown in FIG. 1, the gate, source and drain electrodes of each of the switch elements 22 are electrically connected to a corresponding one of scan lines 16, a corresponding one of data lines 20 and a corresponding one of pixel electrodes 14, respectively. For example, the switch elements 22 may include a switch element 22a, a switch element 22b, a switch element 22c and a switch element 22d. The gate, source and drain electrodes of the switch element 22a are electrically connected to the scan line 16a, the data line 20a and the pixel electrode 14a, respectively; the gate, source and drain electrodes of the switch element 22b are electrically connected to the scan line 16b, the data line 20a and the pixel electrode 14b, respectively; the gate, source and drain electrodes of the switch element 22c are electrically connected to the scan line 16c, the data line 20a and the pixel electrode 14c, respectively; and the gate, source and drain electrodes of the switch element 22d are electrically connected to the scan line 16d, the data line 20a and the pixel electrode 14d, respectively.

As shown in FIG. 1 and FIG. 2, in the top view of the array substrate 1, in a case that one of the traces 18 disposed between one of the switch elements 22 and a corresponding one of the data lines 20, the source electrode of the switch element 22 may overlap the trace 18. For example, the source electrode of the switch element 22a may cross and overlap the trace 18a. The source electrode of the switch element 22c may cross and overlap the trace 18a. The source electrode of the switch element 22d may cross and overlap the trace 18b.

In the embodiment as illustrated in FIG. 1 and FIG. 2, the gate electrodes of the switch elements 22 may be formed of the same conductive layer C1 as the line sections 161 of the scan lines 16. The source electrodes and drain electrodes of the switch elements 22 may be formed of the same conductive layer C2 as the data lines 20. However, it is not limited thereto. Each of the switch elements 22 may further include a semiconductor layer and a gate insulating layer (not shown), wherein the gate insulating layer is disposed between the gate electrode and the semiconductor layer and opposite sides of the semiconductor layer are in contact with the source electrode and the drain electrode, respectively. The switch elements 22 are, for example, bottom gate thin film transistors, but it is not limited thereto. In some embodiments, the switch elements 22 may be other types of thin film transistors, depending on design requirements.

As shown in FIG. 2, the conductive layer C1, the conductive layer C2 and the conductive layer C3 are sequentially disposed on the substrate 12. An insulating layer IN1 is disposed between the conductive layer C1 and the conductive layer C2, and an insulating layer IN2 is disposed between the conductive layer C2 and the conductive layer C3. The insulating layer IN1 and the insulating layer IN2 may have a through hole TH, through which the bridging section 162 may be electrically connected to the corresponding line section 161. Since the traces 18 are formed of the conductive layer C1, and the data lines 20 are formed of the conductive layer C2, the insulating layer IN1 may also exist between the traces 18 and the data lines 20 to reduce the coupling capacitances between the traces 18 and the data lines 20, thereby minimizing abnormality of the display device. In an embodiment, the resistivity of the conductive layer C1 and the resistivity of the conductive layer C2 are lower than the resistivity of the conductive layer C3. For example, the conductive layer C1 and the conductive layer C2 may include metal, and the conductive layer C3 may include transparent conductive material, but it is not limited thereto. The transparent conductive material may, for example, include indium tin oxide (ITO) or any other suitable material. In some embodiments, the pixel electrodes 14 may be formed of the conductive layer C3, but it is not limited thereto.

In some embodiments, the array substrate 1 may further include common lines, e.g., common lines 24 as shown in FIG. 3, which are disposed on the substrate 12 in the active region AA, for transmitting a common voltage. The common lines may, for example, extend along the second direction D2 and formed of the conductive layer C1, but it is not limited thereto. In the top view of the array substrate 1, one of the common lines may overlap the pixel electrodes 14 in the same column, but it not limited thereto.

It is understood from the above description that in this embodiment of dual-gate type of array substrate 1, since the number of the traces 18 disposed in the peripheral region PR at the second side S2 and the third side S3 of the active region AA can be significantly reduced, and the coupling capacitances between the traces 18 and the data lines 20 can also be reduced, the array substrate 1 can meet the requirement on narrow border while improving displaying quality with a reduced number of data lines 20.

The array substrate is not limited to the above embodiments and may include other embodiments. To simplify the description, other embodiments will be labeled with the same reference numerals as the first embodiment. In order to easily compare the differences between the first embodiment and other embodiments, the differences between different embodiments will be mentioned below, and repeated parts will not be described redundantly.

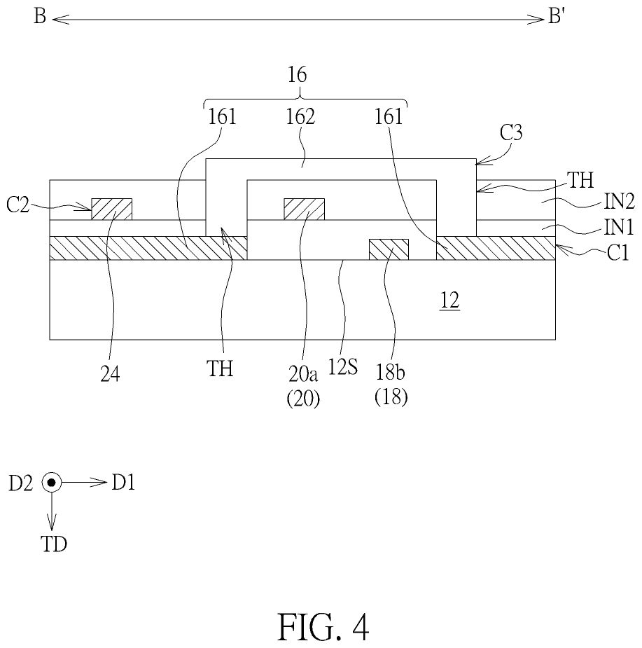

FIG. 3 schematically illustrates a top view of an array substrate according to a second embodiment of the present invention. FIG. 4 schematically illustrates a cross-sectional view of FIG. 3 taken along a line B-B′. As shown in FIG. 3 and FIG. 4, the array substrate 2a in this embodiment differs from the array substrate 1 as illustrated in FIG. 1 in the coupling manner of the pixel electrodes to the scan lines 16 and the data lines 20 through the switch elements 22. In detail, the array substrate 2a may include a substrate 12, a plurality of pixel electrodes 14, a plurality of scan lines 16, a plurality of traces 18, a plurality of data lines 20 and a plurality of switch elements 22, wherein the pixel electrodes 14, the scan lines 16, the traces 18, the data lines 20 and the switch elements 22 are disposed on the substrate 12 in the active region AA. Each of the pixel electrodes 14 is electrically connected to a drain electrode of a corresponding one of the switch elements 22, but it is not limited thereto. The pixel electrodes 14 in this embodiment are arranged in a manner similar to the arrangement of the pixel electrodes 14 shown in FIG. 1, and thus it will not be described redundantly.

In the embodiment as illustrated in FIG. 3, the scan lines 16 are arranged along the second direction D2, and the pixel electrodes 14 in each row are alternately arranged with the scan lines 16 along the second direction D2. In this case, one of the pixel electrodes 14 may be disposed in a region surrounded by two adjacent scan lines 16 and two adjacent data lines 20. Furthermore, each scan line 16 may be electrically connected to the gate electrodes of the switch elements 22, which correspond to the pixel electrodes 14 in the same row, and each data line 20 may be electrically connected to the source electrodes of the switch elements 22, which correspond to the pixel electrodes 14 in the same column, so that the pixel electrodes 14 may be electrically connected to the corresponding data lines 20 through the switch elements 22. For example, the pixel electrode 14a and the pixel electrode 14b may be arranged along the second direction D2, the pixel electrode 14a may be electrically connected to the data line 20a through the switch element 22a, and the pixel electrode 14b may be electrically connected to the data line 20a through the switch element 22b. However, it is not limited thereto.

As shown in FIG. 3, in the top view of the array substrate 2a, the scan lines 16 extend along the first direction D1, and the traces 18 extend along the second direction D2, wherein each of the traces 18 is electrically connected to a corresponding one of the scan lines 16, and at least one of the traces 18 crosses and is electrically insulated from at least one non-corresponding scan line 16, i.e., at least one of the scan lines 16 that is not electrically connected to the at least one of the traces 18. For example, the trace 18a crosses the scan line 16b and is electrically insulated from the scan line 16b. In the embodiment as illustrated in FIG. 3, each scan line 16 may include a plurality of line sections 161 and a plurality of bridging sections 162, and the scan lines 16 may have the same number of bridging sections 162, so as to unify the resistances of the scan lines 16. In an embodiment, the bridging sections 162 of the scan lines 16 may have the same length in the first direction D1, but it is not limited thereto.

In this embodiment, the traces 18 and the data lines 20 are alternately arranged along the first direction D1, but it is not limited thereto. For example, one trace 18 and one data line 20 are disposed between two adjacent columns of pixel electrodes 14, but it is not limited thereto. As shown in FIG. 3, the data lines 20 may be disposed at right sides of corresponding columns of pixel electrodes 14, respectively, but it is not limited thereto. In some embodiments, at least one trace 18 may be disposed between two adjacent data lines 20, but it is not limited thereto.

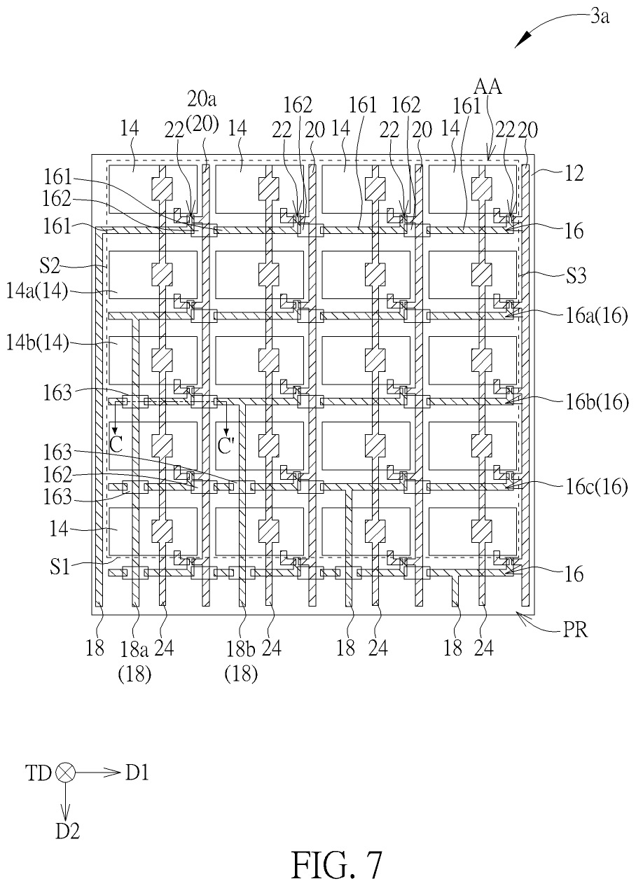

In the embodiment as illustrated in FIG. 3, the traces 18 may have different lengths along the second direction D2 in the top view of the array substrate 2a, so that at least one of the scan lines 16 may not be overlapped with at least one of the traces 18, which are not electrically connected thereto, but it is not limited thereto. Under this circumstance, at least a portion of the bridging sections 162 of the scan lines 16 may overlap the traces 18 and the data lines 20, which are not electrically connected thereto. For example, the scan line 16a may not be overlapped with the trace 18b, and the scan line 16b may overlap the trace 18a and the data line 20a, which are not electrically connected thereto. In some embodiments, the bridging sections 162 of the scan lines 16 may not be overlapped with the traces 18, and under this circumstance, the scan lines 16 may further include bridging sections 163, as shown in FIG. 7.

Similar to the above-described embodiments, the traces 18 in the embodiment as illustrated in FIG. 3 may be arranged along the first direction D1 according to the sequence of the sizes in the lengths of the traces 18. For example, longer traces 18 are closer to the second side S2 of the active region AA, but it is not limited thereto. In some embodiments, the sequence of arranging the traces 18 in the first direction D1 does not follow a length rule.

As shown in FIG. 3 and FIG. 4, the line sections 161 of the scan lines 16 may be formed of the conductive layer C1, the data lines 20 may be formed of the conductive layer C2, and the bridging sections 162 may be formed of the conductive layer C3. Therefore, the bridging sections 162 may be electrically connected to adjacent line sections 161 while being electrically insulated from the traces 18 and the data lines 20. As shown in FIG. 4, an insulating layer IN1 may be disposed between the conductive layer C1 and the conductive layer C2, and an insulating layer IN2 may be disposed between the conductive layer C2 and the conductive layer C3. In this embodiment, the insulating layer IN1 may be used as, for example, the gate insulating layer, but not limited thereto. The sequence to stack conductive layers C1-C3, the insulating layer IN1 and the insulating layer IN2 may be similar to or the same as that illustrated in FIG. 2. Likewise, the coupling capacitances between the traces 18 and the data lines 20 may be reduced accordingly, so as to minimize abnormality of the display device in this embodiment, and thus it will not be described redundantly. Furthermore, the materials of the conductive layer C1, the conductive layer C2 and the conductive layer C3 may be the same as those of the conductive layer C1, the conductive layer C2 and the conductive layer C3 described in the first embodiment, respectively, and thus it will not be described redundantly.

It is to be noted that since the bridging sections 162 are formed of the conductive layer C3, and the resistivity of the conductive layer C3 is greater than resistivity of the conductive layer C1 for forming the line sections 161, it is advantageous to unify resistances of the scan lines 16 by making the scan lines 16 have the same number of bridging sections 162, thereby minimizing signal variation with locations and improving displaying quality of images. Furthermore, since the traces 18 and the bridging sections 162 are formed of different conductive layers C1 and C3, respectively, interference among signals on different scan lines may be mitigated.

As shown in FIG. 3 and FIG. 4, the array substrate 2a may further include a plurality of common lines 24 disposed on the substrate 12 in the active region AA and for transmitting a common voltage. The common lines 24 may, for example, extend along the second direction D2 and formed of the conductive layer C2, but it is not limited thereto. The common lines 24 in the top view of the array substrate 2a may overlap the pixel electrodes 14 in the same column, so as to form storage capacitors with the pixel electrodes 14, but it not limited thereto. In some embodiments, the common lines 24 may be formed of a conductive layer other than the conductive layers C1-C3. Other portions of the array substrate 2a shown in FIG. 3 and FIG. 4 may be similar to or the same as those included in the array substrate described above or below, and thus it will not be described redundantly.

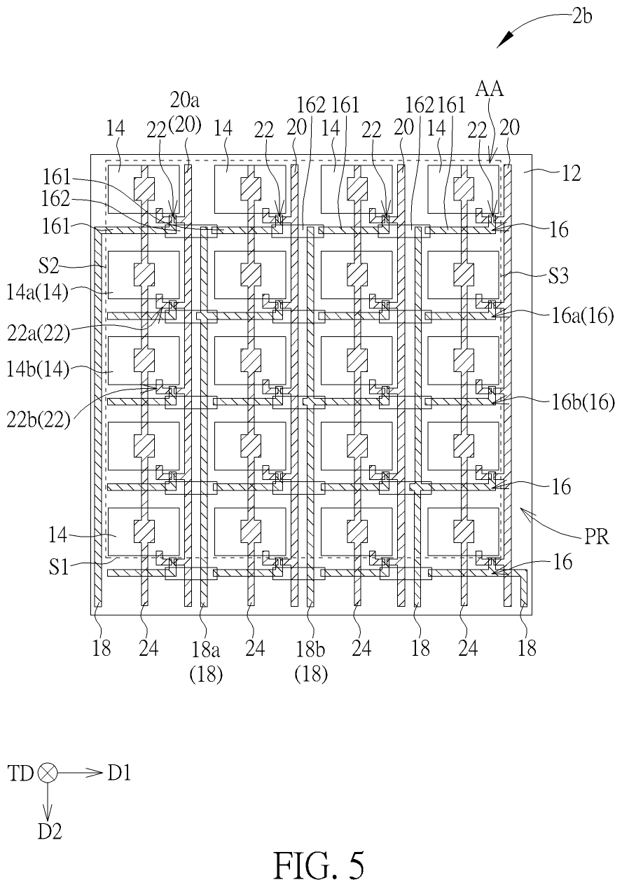

FIG. 5 schematically illustrates a top plan view of an array substrate according to a variation of the second embodiment of the present invention. As shown in FIG. 5, the array substrate 2b in this variation embodiment differs from the array substrate 2a illustrated in FIG. 3 in that the traces 18 in the variation embodiment may have the same length in the active region AA. For example, the trace 18a and the trace 18b have the same length along the second direction D2. Under this circumstance, the trace 18a in the active region AA may overlap the bridging sections 162 of other scan lines, which are not electrically connected thereto, in the top view of the array substrate 2b. Therefore, the coupling capacitance of each of the scan lines 16 with other scan lines 16 may be the same, and the coupling capacitances of the scan lines can be unified, so as to minimize abnormality of the display device and improve displaying quality. Other portions of the array substrate 2b shown in FIG. 5 may be similar to or the same as those included in the array substrate described above or below, and thus it will not be described redundantly.

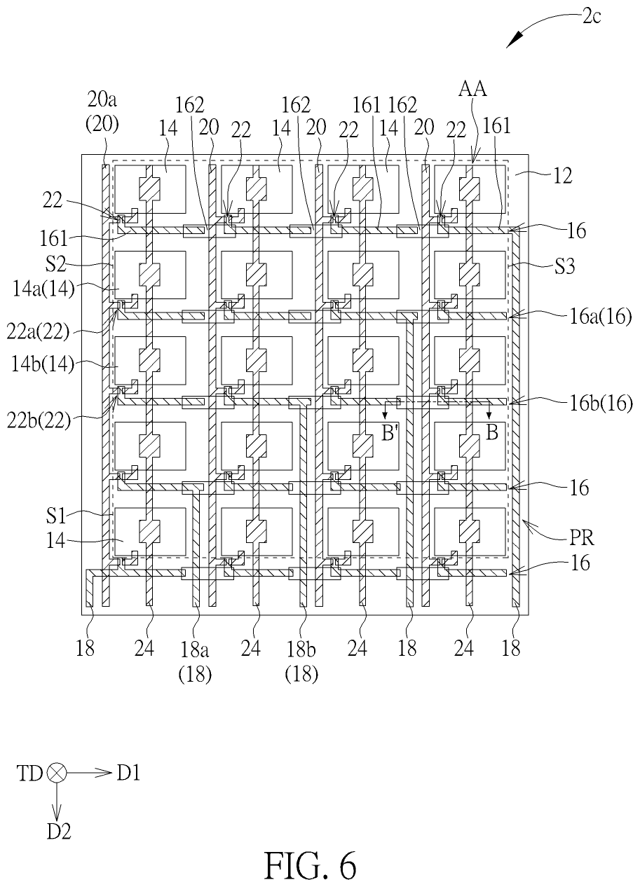

FIG. 6 schematically illustrates a top plan view of an array substrate according to another variation of the second embodiment of the present invention. As shown in FIG. 6, the array substrate 2c in this variation embodiment differs from the array substrate 2a illustrated in FIG. 3 in that the data lines 20 in the variation embodiment may be disposed at respective left sides of corresponding columns of pixel electrodes 14, i.e., the columns of pixel electrodes 14 electrically connected thereto. In some embodiments, the traces 18 may be getting longer along the first direction D1. For example, longer traces 18 are closer to the second side S3 of the active region AA, but it is not limited thereto. Other portions of the array substrate 2c shown in FIG. 6 may be similar to or the same as those included in the array substrate described above or below, and thus it will not be described redundantly.

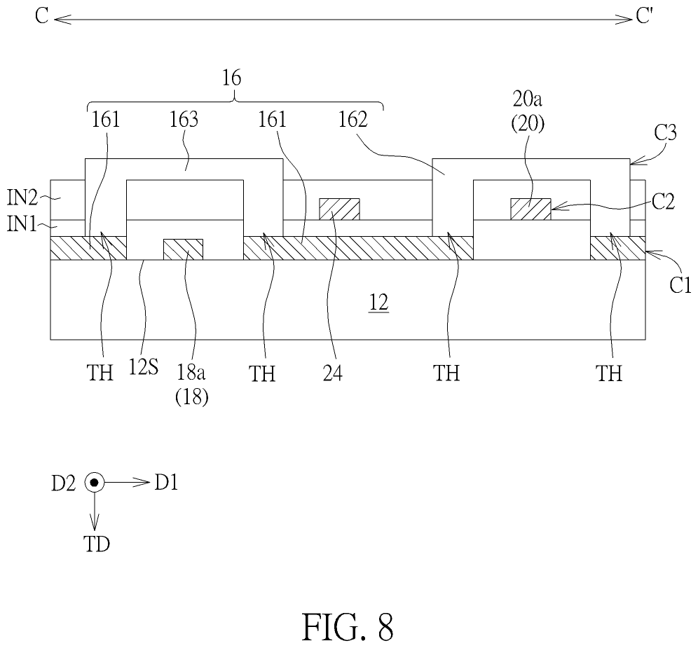

FIG. 7 schematically illustrates a top plan view of an array substrate according to a third embodiment of the present invention. FIG. 8 schematically illustrates a cross-sectional view of FIG. 7 taken along a line C-C′. As shown in FIG. 7, the array substrate 3a in this embodiment differs from the array substrate 2a illustrated in FIG. 3 in that at least one of the traces 18 in this embodiment may overlap at least one of the pixel electrodes 14 in the top view of the array substrate 3a. For example, the trace 18a is connected to the scan line 16a, and the pixel electrode 14b is disposed between the scan line 16a and the first side S1 of the active region AA, so the trace 18a crosses the pixel electrode 14b, and so forth. Under this circumstance, the at least one of the scan lines 16 may further include at least one bridging section 163 in addition to the line sections 161 and the bridging sections 162, and in the top view of the array substrate 3a, the bridging section 163 may be overlapped with and insulated from one of the traces 18. For example, the scan line 16b may further include one bridging section 163, which overlaps the trace 18a electrically connected to the scan line 16a. The scan line 16c may include two bridging sections 163, which overlap the trace 18a and the trace 18b, respectively, and so forth.

In the embodiment as illustrated in FIG. 7, one of the common lines 24 is disposed between one of the traces 18 and one of the data lines 20 in the top view of the array substrate 3a, thereby alleviating the influence of the signal transmitted through the trace 18 on the data signal transmitted through the data line 20, but it is not limited thereto. In some embodiments, the positions of the bridging sections 163 may vary with the positions of the traces 18, and it is not limited to the configuration shown in FIG. 7.

As shown in FIG. 8, the bridging sections 162 and the bridging sections 163 are formed of the same conductive layer, e.g., the conductive layer C3, but it is not limited thereto. In some embodiments, other portions of the array substrate 3a shown in FIG. 7 and FIG. 8 may be similar to or the same as those included in the array substrate described above or below, and thus it will not be described redundantly.

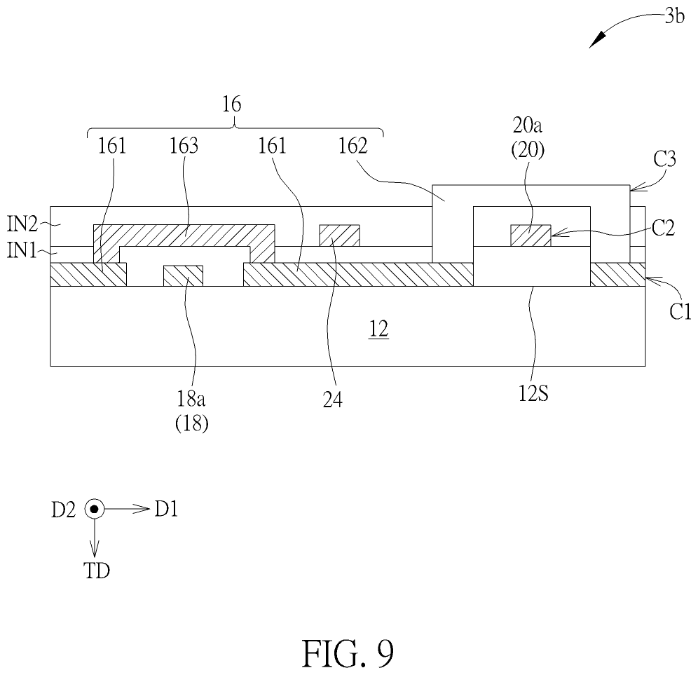

FIG. 9 schematically illustrates a top plan view of an array substrate according to a variation of the third embodiment of the present invention. As shown in FIG. 9, the array substrate 3b in this variation embodiment differs from the array substrate 3a illustrated in FIG. 7 in that the bridging sections 163 and the bridging sections 162 are formed of different conductive layers. For example, the bridging sections 163 and the data lines 20 are formed of the same conductive layer C2. Since the conductive layer C2 may include metal, the influence of the bridging sections 163 on the resistances of the scan lines 16 can be alleviated, so as to unify the resistances of the scan lines. In some embodiments, other portions of the array substrate 3b shown in FIG. 9 may be similar to or the same as those included in the array substrate described above or below, and thus it will not be described redundantly.

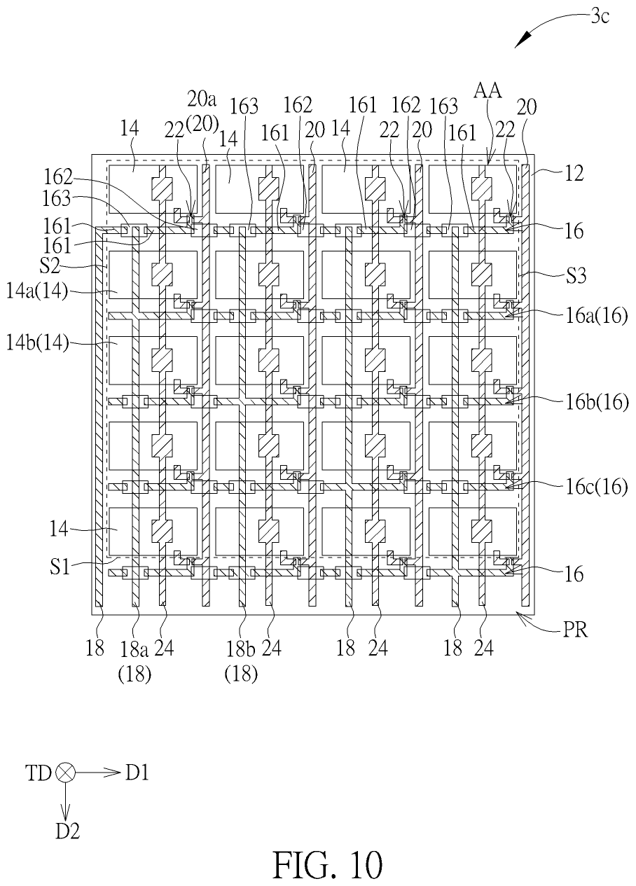

FIG. 10 schematically illustrates a top plan view of an array substrate according to another variation of the third embodiment of the present invention. As shown in FIG. 10, the array substrate 3c in this variation embodiment differs from the array substrate 3a illustrated in FIG. 7 in that each of the scan lines 16 may include a plurality of bridging sections 163, and the scan lines 16 may have the same number of bridging sections 163, so as to unify the resistances of the scan lines. In an embodiment, the bridging sections 163 of the scan lines 16 may have the same length in the first direction D1, but it is not limited thereto. Under this circumstance, the traces 18 in the active region AA may optionally be the same, so that one trace 18 may overlap one of the bridging sections 163 of each scan line 16, which is not electrically connected thereto, in the top view of the array substrate 3c, thereby unifying the coupling capacitance of the scan lines 16. For example, one of the bridging sections 163 of the scan line 16a may overlap the trace 18b electrically connected to the scan line 16b. In some embodiments, other portions of the array substrate 3c shown in FIG. 10 may be similar to or the same as those included in the array substrate described above or below, and thus it will not be described redundantly.

To sum up, in the array substrate according to the present invention, since the traces electrically connected to the scan lines extend from the first side of the active region to the peripheral region, the number of traces located in the peripheral region at the second side and the third side of the active region can be greatly reduced, so that the display device can have a narrow border. Moreover, the traces and the data lines may be formed of different conductive layers to reduce the coupling capacitances between the traces and the data lines, so as to minimize abnormality of the display device. Furthermore, by designing the scan lines with the same number of bridging sections, the resistances of the scan lines may be unified, so as to improve the displaying quality of images.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An array substrate, comprising:
a substrate;
a first pixel electrode and a second pixel electrode disposed on the substrate and arranged along a first direction;
a first scan line and a second scan line disposed on the substrate and extending along the first direction, wherein the first pixel electrode and the second pixel electrode are disposed between the first scan line and the second scan line;
a first trace and a second trace disposed on the substrate and extending along a second direction different from the first direction, wherein the first trace is electrically connected to the first scan line, the second trace is electrically connected to the second scan line, the first trace crosses and is electrically insulated from the second scan line, and the first trace and the second trace are formed of a first conductive layer; and
a data line disposed on the substrate and extending along the second direction, wherein in a top view of the array substrate, the data line is disposed between the first pixel electrode and the second pixel electrode, the data line crosses the second scan line, the data line is formed of a second conductive layer different from the first conductive layer, and the data line is disposed between the first trace and the second trace.

2. The array substrate according to claim 1, wherein the second scan line comprises at least two line sections and at least one bridging section, the at least one bridging section is electrically connected between the at least two line sections, the at least one bridging section is formed of a third conductive layer different from the first conductive layer and the second conductive layer, the at least one bridging section overlaps the first trace in the top view of the array substrate, and the at least two line sections are formed of the first conductive layer.

3. The array substrate according to claim 1, further comprising a first switch element and a second switch element disposed on the substrate, wherein a gate electrode, a source electrode and a drain electrode of the first switch element are electrically connected to the first scan line, the data line and the first pixel electrode, respectively, a gate electrode, a source electrode and a drain electrode of the second switch element are electrically connected to the second scan line, the data line and the second pixel electrode, respectively, and the source electrode of the first switch element overlaps the first trace in the top view of the array substrate.

4. The array substrate according to claim 1, further comprising:
a third pixel electrode and a fourth pixel electrode disposed on the substrate and arranged along the first direction, wherein the first pixel electrode and the third pixel electrode are arranged along the second direction;
a third scan line and a fourth scan line disposed on the substrate and extending along the first direction, wherein the third pixel electrode and the fourth pixel electrode are disposed between the third scan line and the fourth scan line; and
a third switch element and a fourth switch element disposed on the substrate, wherein a gate electrode, a source electrode and a drain electrode of the third switch element are electrically connected to the third scan line, the data line and the third pixel electrode, respectively, and a gate electrode, a source electrode and a drain electrode of the fourth switch element are electrically connected to the fourth scan line, the data line and the fourth pixel electrode, respectively, and wherein in the top view of the array substrate, the source electrode of the third switch element overlaps the first trace, and the source electrode of the fourth switch element overlaps the second trace.

5. The array substrate according to claim 4, wherein the third scan line comprises at least two line sections and at least one bridging section, the at least one bridging section is electrically connected between the at least two line sections, and the at least one bridging section overlaps and is electrically insulated from the first trace and the second trace in the top view of the array substrate.

6. An array substrate, comprising:
a substrate;
a first scan line and a second scan line disposed on the substrate and extending along a first direction, wherein each of the first scan line and the second scan line comprises a plurality of line sections and a plurality of first bridging sections;
a first trace and a second trace disposed on the substrate and extending along a second direction different from the first direction, wherein the first trace is electrically connected to the first scan line, and the second trace is electrically connected to the second scan line; and
a data line disposed on the substrate and extending along the second direction, wherein the data line crosses one of the first bridging sections of the first scan line and one of the first bridging sections of the second scan line,
wherein a number of the first bridging sections of the first scan line is the same as a number of the first bridging sections of the second scan line, and
wherein in a top view of the array substrate, the one of the first bridging sections of the second scan line in the data line overlaps the data line and the first trace.

7. The array substrate according to claim 6, wherein the line sections are formed of a first conductive layer, the data line is formed of a second conductive layer, the first bridging sections are formed of a third conductive layer, and the first trace and the second trace have a same length in the second direction.

8. The array substrate according to claim 6, further comprising:
a first pixel electrode and a second pixel electrode disposed on the substrate and arranged along the second direction; and
a first switch element and a second switch element disposed on the substrate, wherein the first pixel electrode is electrically connected to the data line through the first switch element, and the second pixel electrode is electrically connected to the data line through the second switch element.

9. The array substrate according to claim 6, wherein the first trace overlaps the second pixel electrode in the top view of the array substrate, the second scan line further comprises at least one second bridging section, and the first trace crosses the at least one second bridging section of the second scan line in the top view of the array substrate, and wherein the first bridging sections and the at least one second bridging section of the second scan line are formed of a same conductive layer or formed of different conductive layers.

10. The array substrate according to claim 9, wherein the first scan line further comprises at least one second bridging section, a number of the at least one second bridging section of the first scan line is the same as a number of the at least one second bridging section of the second scan line, and the at least one second bridging section of the first scan line overlaps the second trace.
